(19) United States
(12) Patent Application Publication
(10) Pub. No.: US 2015/0303250 A1
(43) Pub. Date: Oct. 22, 2015

(54) Semiconductor Device Having Shallow Trench Isolation and Method of Forming the Same

(71) Applicant: Micron Technology, Inc., Boise, ID (US)

(72) Inventor: Shigeo ISHIKAWA, Tokyo (JP)

(21) Appl. No.: 14/663,740

(22) Filed: Mar. 20, 2015

(30) Foreign Application Priority Data
Apr. 16, 2014 (JP) 2014-084659

(51) Int. Cl. H01L 29/06; H01L 21/762

(52) U.S. Cl. CPC H01L 29/0649; H01L 21/76229

(57) ABSTRACT

A device includes a first dielectric film formed in a first trench along a first bottom surface portion and a first side surface portion with leaving a first gap in the first trench and a second dielectric film formed in a second trench along a second bottom surface portion and a second side surface portion with leaving a second gap in the second trench. The first bottom surface portion is covered approximately conformably with a first part of the first dielectric film, the first side surface portion is covered approximately conformably with a second part of the first dielectric film, and the first part is larger in thickness than the second part. The second bottom surface portion is covered approximately conformably with a third part of the second dielectric film, the second side surface portion is covered approximately conformably with a fourth part of the second dielectric film, and the third part is larger in thickness than the fourth part.

### BACKGROUND OF THE INVENTION

1. Field of the Invention

The present invention relates to a semiconductor device and a method of manufacturing the same, particularly to a semiconductor device having an STI (Shallow Trench Isolation) structure and a method of manufacturing the same.

Priority is claimed on Japanese Patent Application No. 2014-084659, filed Apr. 16, 2014, the content of which is incorporated herein by reference.

2. Description of the Related Art

In a semiconductor device, such as DRAM (Dynamic Random Access Memory), a dielectric film is formed between elements adjacent to each other so that insulation between the elements is ensured by the dielectric film. An isolation dielectric film is formed by burying a dielectric film in a trench formed on a semiconductor substrate. The progress of microfabrication in recent years has lead to an increase in the aspect ratio of trenches, which makes difficult burying a dielectric film securely in a trench.

An SOD (Spin On Dielectric) method using polysilazane is known as a method of burying a dielectric film securely in a trench with a large aspect ratio. Patent documents 1 and 2 disclose methods of burying a dielectric film in a trench by the SOD method. According to the disclosed methods, the surface of a semiconductor substrate, on which trenches are formed, is coated with a polysilazane-containing material by spin coating to form an SOD film (i.e., film formed by the SOD method). The polysilazane-containing material used in the spin coating process is in a liquid state, thus showing high flowability. For this reason, the SOD film flows well into a trench with a large aspect ratio. Subsequently, an oxidation-annealing treatment is performed to reform and cure the SOD film. As a result, a silicon oxide film serving as an isolation dielectric film is formed.

Patent document 3 discloses a method of forming an isolation dielectric film, according to which after a dielectric film to be buried in trenches is formed by the SOD method, the dielectric film buried in a narrow trench is recessed and a recessed space is filled with a non-flowable second dielectric film formed by HDP-CVD (High Density Plasma-Chemical Vapor Deposition) method.

Patent 4 discloses a method of forming an isolation dielectric film, according to which after a trench is filled completely with an HDP-CVD film (i.e., film formed by the HDP-CVD method), irregularities formed on the surface of the HDP-CVD film are filled with an SOD film and then the surface is flattened by CMP (Chemical Mechanical Polishing) method.

Patent document 5 proposes flowable CVD method in place of the SOD method. A method of burying a dielectric film by the flowable-CVD method is a method by which a flowable silicon compound film (composed mainly of silanol (Si(OH)₄)) is formed by CVD method, using organic silane and organic siloxane as raw materials, and then the silicon compound film is reformed into a silicon oxide film through oxidation reaction. The flowable silicon compound film is capable of flowing into a narrow space as the SOD film is, showing superior burying performance, thus offering an advantage of less void formation. Patent document 5 discloses a method by which trenches with different widths are filled with a flowable CVD film (i.e., film formed by the flowable-CVD method) and with an HDP-CVD film. Specifically, the flowable CVD film is formed such that a narrow trench is filled completely with the film while a wide trench is filled not completely with the film and then the formed flowable CVD film is subjected to an oxidation-annealing treatment, which is followed by complete filling of the wide trench with the HDP-CVD film.

[Patent Document 1] Japanese Laid-Open Patent Publication No. H11-307626

[Patent Document 2] Japanese Laid-Open Patent Publication No. 2005-045230

[Patent Document 3] Japanese Laid-Open Patent Publication No. 2010-263129

[Patent Document 4] Japanese Laid-Open Patent Publication No. 2005-285818

[Patent Document 5] Japanese Laid-Open Patent Publication No. 2012-231007

### SUMMARY

In one embodiment, a semiconductor device may include, a substrate including an upper surface, a first trench selectively formed in the substrate so that the substrate includes a first bottom surface portion and a first side surface portion extending from the first bottom surface portion to the upper surface, the first trench being defined by the first bottom surface portion and the first side surface portion; a second trench selectively formed in the substrate so that the substrate includes a second bottom surface portion and a second side surface portion extending from the second bottom surface portion to the upper surface, the second trench being defined by the second bottom surface portion and the second side surface portion, the second trench being formed larger in width than the first trench; a first dielectric film formed in the first trench along the first bottom surface portion and the first side surface portion with leaving a first gap in the first trench, the first bottom surface portion being covered approximately conformably with a first part of the first dielectric film and the first side surface portion being covered approximately conformably with a second part of the first dielectric film, the first part being larger in thickness than the second part; and a second dielectric film formed in the second trench along the second bottom surface portion and the second side surface portion with leaving a second gap in the second trench, the second bottom surface portion being covered approximately conformably with a third part of the second dielectric film and the second side surface portion being covered approximately conformably with a fourth part of the second dielectric film, the third part being larger in thickness than the fourth part.

In another aspect of the present invention, a semiconductor device may include, a substrate including an upper surface, a first trench selectively formed in the substrate so that the substrate includes a first bottom surface portion and a first side surface portion extending from the first bottom surface portion to the upper surface, the first trench being defined by the first bottom surface portion and the first side surface portion; a second trench selectively formed in the substrate so that the substrate includes a second bottom surface portion and a second side surface portion extending from the second bottom surface portion to the upper surface, the second trench being defined by the second bottom surface portion and the second side surface portion, the second trench being formed deeper in depth than the first trench; a first dielectric film formed in the first trench along the first bottom surface portion and the first side surface portion with leaving a first gap in the first trench, the first bottom surface portion being covered approximately conformably with a first part of the first dielectric film and the first side surface portion being covered approximately conformably with a second part of the first dielectric film, the first part being larger in thickness than the second part; and a second dielectric film formed in the second trench along the second bottom surface portion and the second side surface portion with leaving a second gap in the second trench, the second bottom surface portion being covered approximately conformably with a third part of the second dielectric film and the second side surface portion being covered approximately conformably with a fourth part of the second dielectric film, the third part being larger in thickness than the fourth part.

In another embodiment, a method of forming a semiconductor device may include, forming a mask film having a first hole pattern and a second hole pattern on an upper surface of a substrate; forming a first trench at the first hole pattern and a second trench at the second hole pattern in the substrate such that the first trench has a first bottom surface portion and a first side surface portion extending from the first bottom surface portion to the upper surface of the substrate, the second trench has a second bottom surface portion, which is larger in width than the first bottom surface portion, and a second side surface portion extending from the second bottom surface portion to the upper surface of the substrate; forming a first isolation film to cover an upper surface of the mask film, the first bottom surface portion and the first side surface portion, the second bottom surface portion and the second side surface portion with remaining a first gap in the first trench and a second gap in the second trench, a first part of the first isolation film covering the first bottom surface portion being controlled to be thicker than a second part of the first isolation film covering the first side surface portion, a third part of the first isolation film covering the second bottom surface portion being controlled to be thicker than a fourth part of the first isolation film covering the second side surface portion; forming a second isolation film on the first isolation film to fill the first gap and the second gap; removing a part of the second isolation film to expose an upper surface of the mask film.

According to the present invention, a first portion of a first dielectric film and a third portion of a second dielectric film are formed on the bottom surfaces of trenches, respectively, such that the dielectric film portions on the bottom surfaces are thicker than dielectric film portions formed on the side surfaces. In this configuration, the bottom surfaces of the trenches are protected by the first and third portions. When a second isolation film that invites a stress to a substrate is formed on the first and second dielectric films, therefore, the first and second portions formed on the bottom surfaces function to prevent the creation of a stress. As a result, development of a crystal defect in the substrate is prevented.

### BRIEF DESCRIPTION OF THE DRAWINGS

The above features and advantages of the present invention will be more apparent from the following description of certain preferred embodiments taken in conjunction with the accompanying drawings, in which:

FIG. 1A is a plan view showing a layout of active areas of a semiconductor device according to preferred embodiments of the present invention;

FIG. 1B is a sectional view along an A-A′ line of the semiconductor device according to the preferred embodiments of FIG. 1A;

FIG. 2A is a plan view showing the semiconductor device according to the preferred embodiments of the present invention;

FIG. 2B is a sectional view along a B-B′ line of the semiconductor device according to the preferred embodiments of FIG. 2A;

FIG. 2C is a sectional view along a C-C′ line of the semiconductor device according to the preferred embodiments of FIG. 2A;

FIG. 3 is a process sectional view equivalent to FIG. 1B, showing a process included in a method of manufacturing the semiconductor device according to a preferred first embodiment of the present invention;

FIG. 4 is a process sectional view showing a process following the process of FIG. 3 included in the method of manufacturing the semiconductor device according to the preferred first embodiment of the present invention;

FIG. 5 is a process sectional view showing a process following the process of FIG. 4 included in the method of manufacturing the semiconductor device according to the preferred first embodiment of the present invention;

FIG. 6 is a process sectional view showing a process following the process of FIG. 5 included in the method of manufacturing the semiconductor device according to the preferred first embodiment of the present invention;

FIG. 7 is a process sectional view showing a process following the process of FIG. 6 included in the method of manufacturing the semiconductor device according to the preferred first embodiment of the present invention;

FIG. 8 is a process sectional view showing a process following the process of FIG. 7 included in the method of manufacturing the semiconductor device according to the preferred first embodiment of the present invention;

FIG. 9 is a sectional view equivalent to FIG. 1B, showing a configuration of the semiconductor device according to a preferred second embodiment of the present invention;

FIG. 10 depicts an example of results of scanning electron microscopy of a section of the semiconductor device according to the preferred embodiments of the present invention;

FIG. 11 is a process sectional view equivalent to FIG. 1B, showing a process included in a method of manufacturing the semiconductor device according to a preferred third embodiment of the present invention; and

FIG. 12 is a process sectional view showing a process following the process of FIG. 11 included in the method of manufacturing the semiconductor device according to the preferred third embodiment of the present invention.

### DETAILED DESCRIPTION OF THE PREFERRED EMBODIMENTS

Hereinafter, knowledge the inventor has acquired through experiments and examinations will first be explained before description of preferred embodiments of the present invention.

The inventor has examined various methods of forming isolation regions in a DRAM (Dynamic Random Access Memory), which, among ordinary semiconductor devices in wide use, requires particular micropatterns. It is known that the DRAM has a memory cell area in which a plurality of the same micropatterns formed by the latest technology are arranged repeatedly, and a peripheral circuit area for controlling or driving memory cells. The peripheral circuit area includes a direct peripheral circuit area in which direct peripheral circuits patterned in conformity to a rule slightly layer than a rule applied to memory cell patterning are arranged, and an in-direct peripheral circuit area in which power circuits, etc., made up of patterns larger than direct peripheral circuit patterns are arranged. Hence patterns included in the DRAM are roughly classified into three patterns different in occupation area from each other. As the size of the semiconductor device is reduced further, an STI (Shallow Trench Isolation) structure, in which a trench formed on the semiconductor device is filled with a dielectric film, has become the main stream of isolation region structures.

To deal with microscopic isolation regions, the inventor has studied at first a hybrid structure isolation method by which microscopic STI trenches in the memory cell area are filled completely with an SOD film as wide STI trenches that cannot be filled completely with the SOD film in the direct peripheral circuit region and in-direct peripheral circuit region are filled with a non-flowable HDP-CVD film. However, the inventor found a problem that if the SOD film is used as an isolation dielectric film, as described above, a dislocation defect develops in the semiconductor substrate due to volumetric shrinkage occurring during an oxidation-annealing treatment. A crystal defect, i.e., dislocation defect leads to the generation of a junction leak current, thus creating the cause of hampering the normal operation of a transistor. In such a case, ensuring the reliability of the semiconductor device is difficult. This isolation method, therefore, cannot be adopted.

The inventor has also studied a hybrid structure including a silicon oxide film formed by flowable CVD method to have flowability as the SOD film has and a silicon oxide film formed by HDP-CVD method to have no flowability. The inventor, however, found that this hybrid structure also involves development of a dislocation defect. The inventor's study has revealed that this dislocation defect does not develop in the memory cell area and in-direct peripheral circuit area but develop only in the direct peripheral circuit area. The inventor's inference attributes this phenomenon to the fact that in the direct peripheral circuit area, isolation regions counter to each other across an active area are different in width and this width difference creates unbalanced left and right shrinkage stresses during the oxidation-annealing treatment on the flowable CVD film and to the fact that the active areas in the direct peripheral circuit area are not as wide as active areas in the in-direct peripheral circuit area and therefore have insufficient mechanical strength that makes the active areas weak to a stress. Active areas in the memory cell area are even narrower than the active areas in the direct peripheral circuit area and are therefore weak to a stress, but balanced left and right shrinkage stresses in the memory cell area prevents development of a dislocation defect in the area. It has also been inferred that being wider than the active areas in the direct peripheral circuit area, the active areas in the in-direct peripheral circuit area have greater mechanical strength that makes the active areas unsusceptible to a stress.

To avoid development of a dislocation defect, the inventor has studied various oxidation-annealing conditions and film formation conditions under which the SOD film and flowable CVD film are formed. The inventor has managed to find a condition for reducing the frequency of dislocation defect development but failed to find a condition for totally eliminating dislocation defects. This leads to a conclusion that the hybrid structure constructed by forming a flowable film first, which is subjected to the oxidation-annealing treatment, and then forming an HDP-oxide film has difficulty in totally eliminating dislocation defects. A further detailed observation of development of dislocation defects has revealed that the location of development of a dislocation defect is closely related to an end of an active area in contact with an isolation region.

Based on the above fact, the inventor has reasoned that a dislocation defect starts developing at the end of the active area as a result of concentration of a shrinkage stress, which is caused by the oxidation-annealing treatment on the flowable film, on the end of the active area in contact with the bottom corner of the isolation region. The inventor has thus reached an idea that an isolation film structure that prevents concentration of a stress on the end of the active area in contact with the bottom corner of the isolation region should be realized to avoid development of a dislocation defect. Hence the inventor has come up with a method of first forming a first isolation film made of a non-flowable dielectric film and covering the side surface and bottom surface of the isolation region with the first isolation film and then forming a flowable film and performing the oxidation-annealing treatment to overlay a second isolation film on the first isolation film. According to this method, the first isolation film functions as a stress barrier film for avoiding stress concentration on the bottom corner.

An HDP-CVD film made of a silicon oxide film can be used as the first isolation film. The inventor has further studied a method of forming the first isolation film and found a condition under which during film formation in each trench with any given width in the direct peripheral circuit area and in-direct peripheral circuit area, a deposition rate at the trench side surface can be reduced to 1/10 or less of a deposition rate at the trench bottom surface, and even for the case of a trench with the smallest width in the memory cell area, the deposition rate at the side surface is reduced to the same extent without blocking the trenches' opening. Under this condition, in each trench with any given width, the side surface is covered with an HDP-CVD film thinner than the same on the bottom surface as the bottom surface is covered with an HDP-CVD film uniform in thickness for each trench. Experiments have verified the fact that a hybrid structure in which the non-flowable first isolation film is overlaid with the second isolation film made by oxidatively annealing the flowable film totally eliminates dislocation defects. According to the film formation method employing this condition, a stress barrier film can be formed on the bottom of each trench with a different width. Hence development of a dislocation defect can be avoided in each area, regardless of the width of the trench.

A preferred first embodiment of the present invention will hereinafter be described in detail with reference to drawings.

(Semiconductor Device)

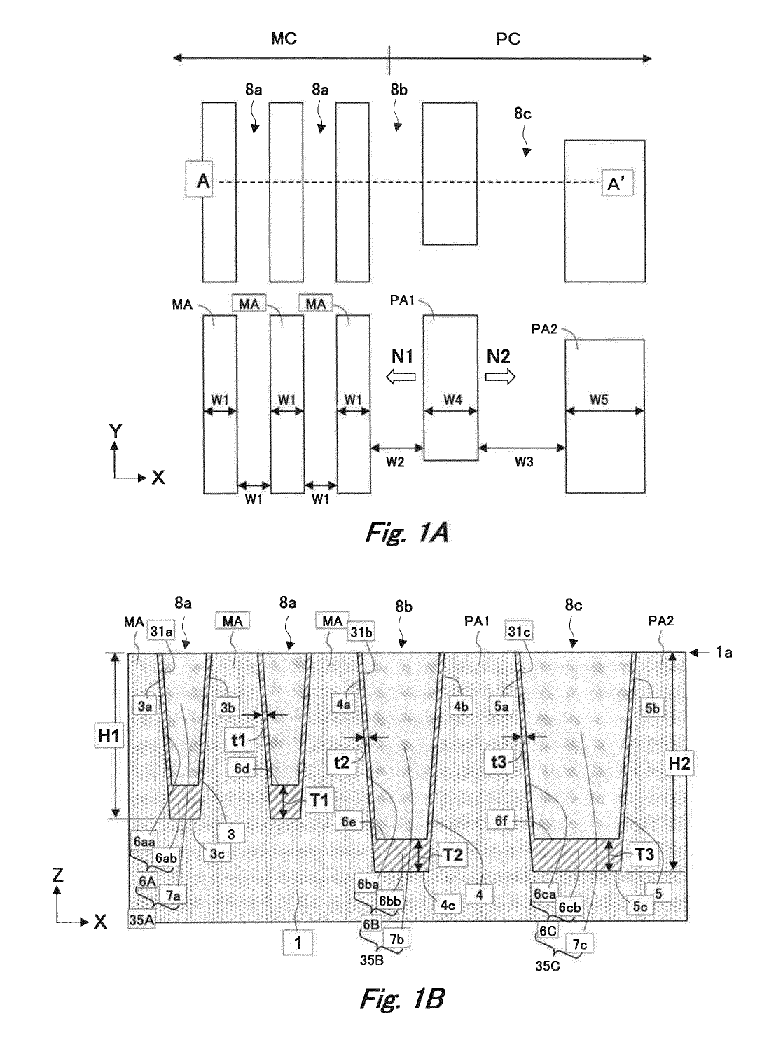

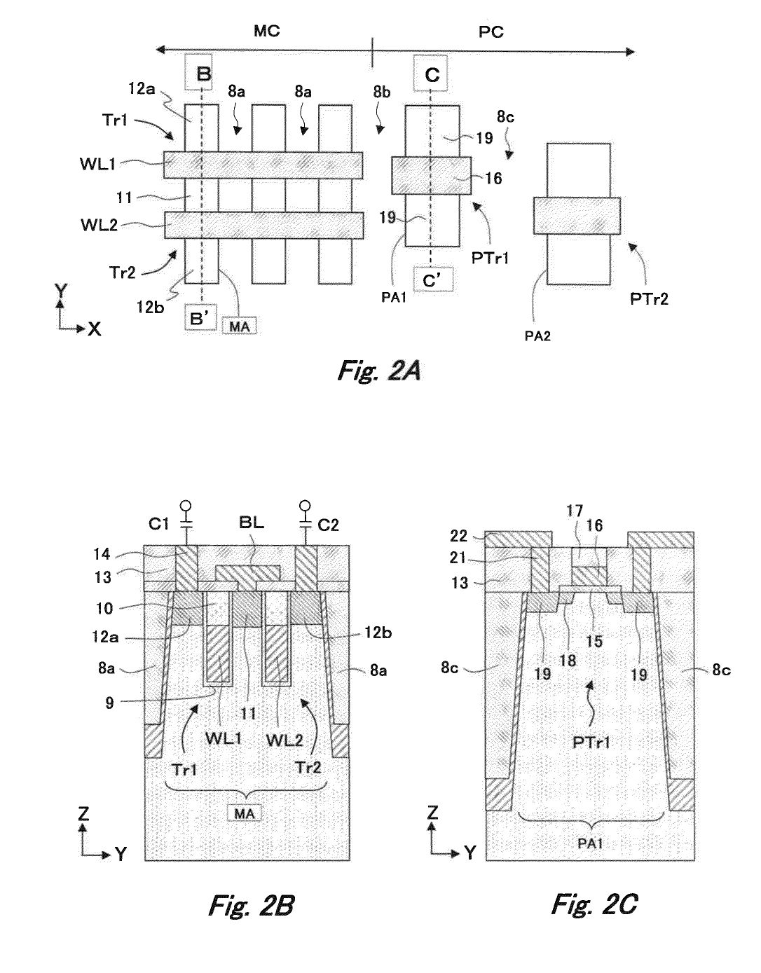

FIGS. 1A, 1B, 2A, 2B, and 2C are diagrams showing a DRAM as a semiconductor device according to preferred embodiments of the present invention. FIG. 1A is a plan view showing a layout of active areas. FIG. 1B is a sectional view along an A-A′ line of FIG. 1A. FIG. 2A is a more specific plan view of the DRAM. FIG. 2B is a sectional view along a B-B′ line of FIG. 2A. FIG. 2C is a sectional view along a C-C′ line of FIG. 2A. The semiconductor device described in the first embodiment is a semiconductor memory device, such as DRAM and NAND flash, but may be provided as other forms of devices.

The plan view of FIG. 1A will be referred to. The DRAM includes a memory cell area MC disposed on one main surface of a semiconductor substrate, and a peripheral circuit area PC for controlling and driving memory cells.

In the memory cell area MC, multiple cell active areas MA each having a width W1 in the X direction of, for example, 30 nm are arranged in the X and Y directions. The cell active areas MA and peripheral active areas PA1 and PA2, which will be described later, make up a part of the semiconductor substrate. For convenience, FIG. 1A depicts each of the cell active areas MA as a rectangular whose longitudinal direction matches the Y direction, but the shape of the cell active area MA is not limited to this. For example, the cell active area MA may be of a shape whose longitudinal direction matches a direction tilted toward an orthogonal axis of the X direction and the Y direction or a shape set diagonal against the X direction or the Y directions. The length of the cell active area in the Y direction is about 5 times the width W1 in the X direction. The memory cell area MC usually includes approximately 10 million cell active areas MA, but FIG. 1A depicts 6 cell active areas MA out of 10 million cell active areas MA. Each cell active area MA is surrounded with first isolation regions 8a and is isolated from a different cell active area MA. Each first isolation region 8a has a first width W1 in the X direction, which first width W1 is about 30 nm and is therefore the same as the width W1 in the X direction of the cell active area MA. Cell active areas MA adjacent to each other in the Y direction are also isolated from each other via the first isolation region 8a.

The peripheral circuit area PC includes peripheral first active areas PA1, which are direct peripheral circuit areas in which direct peripheral circuits, such as a column decoder, row decoder, read/write amplifier, command input circuit, address input circuit, and data input/output circuit, are arranged, and peripheral second active area PA2, which are in-direct peripheral circuit areas in which in-direct peripheral circuits, such as a power circuit, are arranged. For simpler explanation, FIG. 1A depicts two peripheral first active areas PA1 and two peripheral second active areas PA2, but more first and second active areas PA1 and PA2 are actually provided. Each peripheral first active area PA1 has a width W4 in the X direction of, for example, 35 to 50 nm, while each peripheral second active area PA2 has a width W5 in the X direction of, for example, 60 to 80 nm. For example, the plane shape of each of the peripheral first active area PA1 and the peripheral second active area PA2 is a rectangular whose longitudinal direction matches the Y direction, but is not limited to such a rectangular. Both peripheral active areas may be of a shape whose width in the Y direction is determined arbitrarily.

The peripheral first active area PA1 is sandwiched between a second isolation region 8b adjacent in the X direction to the memory cell area MC and a third isolation region 8c adjacent to the peripheral second active area PA2. The second active area PA2 is surrounded with third isolation regions 8c. The second isolation region 8b has a second width W2 in the X direction of, for example, 50 to 70 nm, while the third isolation region 8c has a third width W3 in the X direction of, for example, 140 nm or more. The second and third isolation regions 8b and 8c may have various configurations with different widths. Since it is impossible to describe all conceivable configurations, the isolation regions with the above widths W2 and W3, respectively, are typically described as the second isolation region 8b and the third isolation region 8c. What should be noted is that the first, second, and third isolation regions 8a, 8b, and 8c are different from each other in their widths in the X direction.

The sectional view of FIG. 1B will then be referred to. The first isolation region 8a having the first width W1, the second isolation region 8b having the second width W2, and the third isolation region 8c having the third width W3 are formed on the upper surface 1a of the semiconductor substrate 1, as openings with respective widths. The size relation between the first to third widths W1 to W3 is W1<W2<W3. The isolation regions 8a, 8b, and 8c arranged on the upper surface demarcate the cell active areas MA, the peripheral first active areas PA1, and the peripheral second active areas PA2.

The active areas are isolated from each other via the isolation regions 8a, 8b, and 8c. The isolation regions 8a, 8b, and 8c are composed of isolation dielectric films 35A, 35B, and 35C filling first, second, and third trenches 3, 4, and 5 formed in the semiconductor substrate 1, respectively. The first trench 3 is made up of a first bottom surface portion 3c and first side surface portions 3a and 3b. The second trench 4 is made up of a second bottom surface portion 4c and second side surface portions 4a and 4b. The third trench 5 is made up of a third bottom surface portion 5c and third side surface portions 5a and 5b. Each side surface portion extends from each corresponding bottom surface portion to the upper surface 1a of the semiconductor substrate.

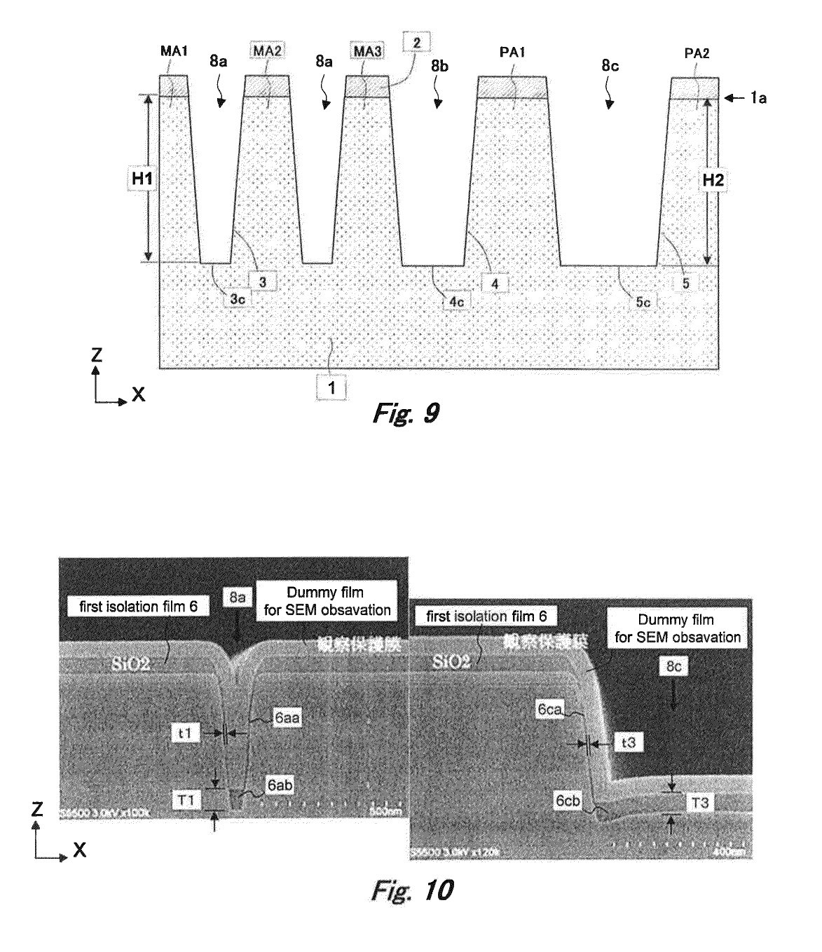

The first depth H1 of the first trench 3, that is, the depth from the upper surface 1a of the semiconductor substrate to the first bottom surface portion 3c is, for example, determined to be 250 nm. The third depth H2 of the third trench 5, that is, the depth from the upper surface 1a of the semiconductor substrate to the third bottom surface portion 5c is, for example, determined to be 350 nm. The depth of the second trench 4 is depicted as the same as that of the third trench 5. The depth of the second trench 4 is greater than the first depth H1 of the first trench 3 and is equal to or smaller than the third depth H2 of the third trench 5. The trenches are formed by anisotropic dry etching, whose characteristics create depth differences between the trenches. By adjusting conditions for the anisotropic dry etching, the trenches' depths can be made equal, which will be depicted in later in FIG. 9.

As shown in FIG. 1B, the trenches 3, 4, and 5 are filled with the isolation dielectric films 35A, 35B, and 35C, respectively, each of which has a laminated structure composed of a first isolation film 6 made of a silicon oxide and a second isolation film 7 also made of a silicon oxide. The first isolation film 6 in contact with the inner surface of the first trench 3 is referred to as first dielectric film 6A, the same in contact with the inner surface of the second trench 4 is referred to as second dielectric film 6B, and the same in contact with the inner surface of the third trench 5 is referred to as third dielectric film 6C.

The first dielectric film 6A is composed of a first portion 6ab uniformly covering the first bottom surface portion 3c and having a first thickness T1, and a second portion 6aa uniformly covering the first side surface portions 3a and 3b and having a second thickness t1. The first thickness T1 is larger than the second thickness t1. The surface 6d of the first dielectric film 6A disposed on the inner surface of the first trench 3 makes up a first gap 31a, which is filled with a second isolation film 7a. Respective upper ends of the first dielectric film 6A and the second isolation film 7a are co-planar with the upper surface 1a of the semiconductor substrate. The above statement “uniformly covering the first side surface portions 3a and 3b” means that the second portion 6aa of the first dielectric film 6A extends as a film of a uniform thickness, from the upper surface of the first bottom surface portion 6ab to the upper surface of the semiconductor substrate along the whole side surface. This interpretation applies also to the following description.

The second dielectric film 6B is composed of a third portion 6bb uniformly covering the second bottom surface portion 4c and having a third thickness T2, and a fourth portion 6ba uniformly covering the second side surface portions 4a and 4b and having a fourth thickness t2. The third thickness T2 is larger than the fourth thickness t2. The surface 6e of the second dielectric film 6B disposed on the inner surface of the second trench 4 makes up a second gap 31b, which is filled with a second isolation film 7b. Respective upper ends of the second dielectric film 6B and the second isolation film 7b are co-planar with the upper surface 1a of the semiconductor substrate.

The third dielectric film 6C is composed of a fifth portion 6cb uniformly covering the third bottom surface portion 5c and having a fifth thickness T3, and a sixth portion 6ca uniformly covering the third side surface portions 5a and 5b and having a sixth thickness t3. The fifth thickness T3 is larger than the sixth thickness t3. The surface 6f of the third dielectric film 6C disposed on the inner surface of the third trench 5 makes up a third gap 31c, which is filled with a second isolation film 7c. Respective upper ends of the third dielectric film 6C and the second isolation film 7c are co-planar with the upper surface 1a of the semiconductor substrate.

According to the semiconductor device of this embodiment, the ratio of the second thickness t1 to the first thickness T1 of the first dielectric film 6A, the ratio of the fourth thickness t2 to the third thickness T2 of the second dielectric film 6B, and the ratio of the sixth thickness t3 to the fifth thickness T3 of the third dielectric film 6C are all equal to each other.

FIG. 10 depicts an example of results of scanning electron microscopy (SEM) of a sectional shape during an intermediate process by which a trench equivalent to the first trench 3 and a trench equivalent to the third trench 5 are formed on the semiconductor substrate 1 and then the first isolation film 6 is formed. A film formed on the surface of the substrate is a dummy silicon film that is formed to enhance the contrast of a scanning electron microscopic image. The second thickness t1 of the second portion 6aa making up the first dielectric film 6A is 5 nm, while the first thickness T1 of the first portion 6ab making up the first dielectric film 6A is 75 nm. The ratio of the second thickness t1 to the first thickness T1 is, therefore, 1/15. Similarly, in the wider trench equivalent to the third trench 5, the ratio of the sixth thickness t3 to the fifth thickness T3 is also 1/15. This example thus demonstrates that the ratio of the thickness at the side surfaces to the thickness at the bottom surface is equal in each trench with any given width, regardless of the size of the width.

According to the semiconductor device of this embodiment, it is preferable that each of the first, second, and third dielectric films 6A, 6B, and 6C disposed in trenches with different widths, respectively, be formed such that the ratio of the thickness of the dielectric film covering the side surface portions to the thickness of the dielectric film covering the bottom surface portion is determined to be 1/10 or less. Consequently, each of the dielectric films 6A to 6C so functions as to elevate the position of the bottom surface of each trench while keeping a positional shift of the trenches' side surfaces small. Hence each of the dielectric films 6A to 6C may be referred to as bottom-raised liner film. To avoid development of a dislocation defect, the thickness T of the film formed on the bottom surface portion of each of the dielectric films 6A to 6C should preferably be ⅕ to ½ of the depth H2 of the third trench 5. If the thickness T is smaller than ⅕ of the depth H2, avoiding dislocation development becomes difficult. If the thickness T is larger than ½ of the depth H2, on the other hand, it makes difficult maintaining the thickness uniformity of the first dielectric film 6A covering the first side surface portions 3a and 3b of the first trench 3 with the narrowest opening. In such a case, the opening of the first trench 3 is blocked easily, which facilitates formation of a void in the trench. When the depth H2 of the third trench is determined to be, for example, 350 nm, as in the case of this embodiment, the secondary thickness T should preferably be determined to be 70 to 175 nm.

FIG. 1B is referred to again. As described above, for example, when the first dielectric film 6A is disposed in the first trench, the first gap 31a is formed as the gap demarcated by the surface of the first dielectric film 6A. The first gap 31a is filled with the second isolation film 7a. Similarly, the second gap 31b in the second trench 4 is filled with the second isolation film 7b and the third gap 31c in the third trench 5 is filled with the second isolation film 7c. The second isolation films 7a, 7b, and 7c are each formed by a process of first forming a flowable film, such as SOD film and flowable CVD film, and then subjecting the flowable film to an oxidation-annealing treatment, which process will be described in detail later when a method of manufacturing the semiconductor device is explained. If the second isolation films 7a, 7b, and 7c are formed without forming the first to third dielectric films 6A, 6B, and 6C, the flowable film shrinks when the second isolation films 7 are formed by the oxidation-annealing treatment. This creates a stress to the semiconductor substrate. As a result, tensile stresses N1 and N2 are applied to both sides in the X direction of the peripheral first active area PA1, as shown in FIG. 1A. At this time, because the volume of the flowable film in the second isolation region 8b located on the left to the peripheral first active area PA1 is smaller than the same in the third isolation region 8c located on the right to the peripheral first active area PA1, the stress N1<the stress N2 results, which indicates a state of unbalanced stresses. When a portion of stress resulting from the unbalanced stresses exceeds the stress critical point of the silicon, a dislocation defect develops. Experimental results have verified that a dislocation defect starts developing at the peripheral first active area PAL According to this embodiment, however, the non-flowable first to third dielectric films 6A, 6B, and 6C are formed so that they cover the side surfaces and bottom surfaces including bottom corners of the trenches. In other words, the first to third dielectric films 6A, 6B, and 6C that do not accompany stress creation or cancel out stresses applied by the second isolation films 7a, 7b, and 7c protect the bottoms of respective trenches. As a result, development of a dislocation defect can be avoided.

FIGS. 2A, 2B, and 2C will then be referred to. FIG. 2A is a plan view, FIG. 2B is a sectional view along a B-B′ line of FIG. 2A, and FIG. 2C is a sectional view along a C-C′ line of FIG. 2A

As shown in FIGS. 2A and 2B, multiple cell active areas each sandwiched between first isolation regions 8a are arranged in the memory cell area MC. Two buried word lines (hereinafter, simply referred to as word lines) WL1 and WL2 are arranged such that they extend in the X direction across the multiple cell active areas MA. Each active area MA is thus divided into a bit diffusion layer 11, a first capacitance diffusion layer 12a, and a second capacitance diffusion layer 12b. The word line WL serving as the gate electrode of a transistor is disposed on a gate dielectric film 9 covering the inner surface of a trench formed on the semiconductor substrate 1. On the upper surface of the word line WL, a cap dielectric film 10 is disposed. The bit diffusion layer 11, a first word line WL1, and the first capacitance diffusion layer 12a make up a first transistor Tr1. The bit diffusion layer 11, a second word line WL2, and the second capacitance diffusion layer 12b make up a second transistor Tr2. The first transistor Tr1 and the second transistor Tr2 are buried-gate MOS transistors.

On the upper surface of the bit diffusion layer 11, the bit line BL is disposed, which is covered with an interlayer dielectric film 13. Capacitance contact plugs 14 are formed such that they penetrate the interlayer dielectric film 13 and connect to capacitance diffusion layers 12a and 12b. Capacitances C1 and C2 are disposed such that they are connected to the upper surfaces of the capacitance contact plugs 14. A basic memory cell of the DRAM is configured in this manner.

FIGS. 2A and 2C will then be referred to. The peripheral first active area PA1 is disposed such that it is sandwiched between the third isolation regions 8c equivalent to the wider trenches. On the peripheral first active area PA1, a peripheral gate electrode 16 is disposed to extend, for example, in the X direction. Source/drain diffusion layers 19 are disposed on both sides in the Y direction of the peripheral gate electrode 16, respectively. LDD (Lightly Dosed Drain) diffusion layers 18 are arranged to be in contact with the source/drain diffusion layers 19. On the upper surface of the semiconductor substrate 1, a peripheral gate dielectric film 15 is disposed, which is overlaid with the peripheral gate electrode 16, whose upper surface is covered with a cover dielectric film 17. The first interlayer dielectric film 13 is so disposed as to cover the cover dielectric film 17. Peripheral contact plugs 21 are formed such that they penetrate the interlayer dielectric film 13 and connect to the source/drain diffusion layers 19. Peripheral wiring 22 is disposed such that it is connected to the upper surfaces of the peripheral contact plugs 21. The peripheral wiring 22 is further overlaid with multiple wiring layers and interlayer dielectric films (which are not depicted) to make up the DRAM.

(Method of Manufacturing Semiconductor Device)

A method of manufacturing the semiconductor device according to this embodiment will then be described in detail, referring to FIGS. 1A, 1B, and 3 to 8. In the following description, the semiconductor substrate 1 is provided as a p-type single crystal silicon substrate. The semiconductor substrate 1, however, may be provided as a different type of silicon substrate.

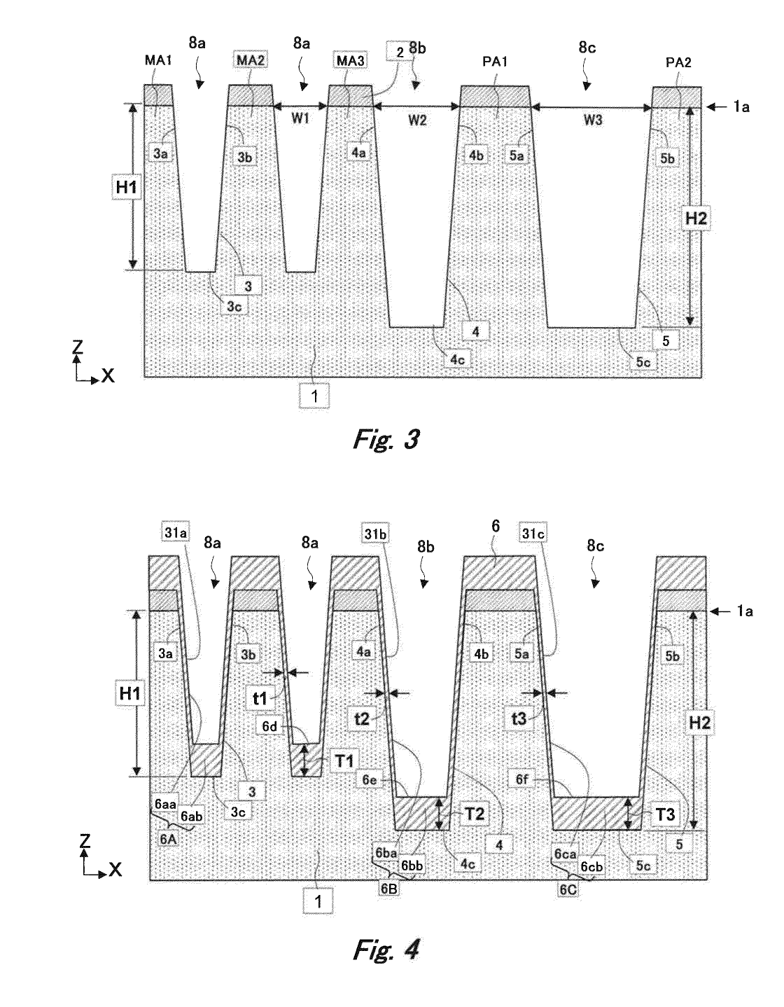

FIG. 3 will first be referred to. The surface of the semiconductor substrate 1 made of silicon is thermally oxidated to form a pad oxide film (not depicted) for protecting the surface. Subsequently, a silicon nitride film of 50 nm in thickness is formed by the known CVD process to cover the entire surface with the silicon nitride film. A photoresist (not depicted) is then applied to the silicon nitride film by photolithography to form patterns of multiple cell active areas MA in the memory cell area MC and patterns of peripheral first active areas PA1 and peripheral second active areas PA2 in the peripheral circuit area PC, as shown in FIG. 1A. Subsequently, the silicon nitride film is etched by the known anisotropic dry etching, using the patterned photoresist as a mask, to form a pattern of a mask film 2. The photoresist is then removed.

Subsequently, the pad oxide film and the semiconductor substrate 1 are etched by the anisotropic dry etching, using the mask film 2 as a mask, to form the first trench 3, second trench 4, and third trench 5. It is preferable that this anisotropic dry etching be performed using an inductive coupled plasma etching apparatus. One example of etching conditions to apply is a condition under which, for example, a mixed gas plasma made up of hydrogen bromide (HBr) of 70 sccm, chloride (Cl₂) of 70 sccm, sulfur hexafluoride (SF₆) of 10 sccm, and oxygen (O₂) of 20 sccm is used with pressure of 20 mToor, source high-frequency power of 1500 W, and ion-accelerating bias power of 200 W being applied. An etching time is set so that the depth H1 of the first trench amounts to about 250 nm deep from the upper surface 1a of the semiconductor substrate 1. When the depth H1 is determined to be about 250 nm, the depth H2 of the third trench 5 is determined to be about 350 nm and the depth of the second trench 4 is determined to be a depth between the depth H1 of the first trench 3 and the depth H2 of the third trench 5.

In this manner, the first trench 3 whose first width W1 in the X direction along the upper surface 1a of the semiconductor substrate 1 is, for example, 30 nm is formed. Similarly, the second trench 4 whose second width W2 is 60 nm and the third trench 5 whose third width W3 is 150 nm are also formed. The first isolation trench 3 has a first side surface portion composed of the side surfaces 3a and 3b opposing to each other in the X direction, and a first bottom surface portion composed of the bottom surface 3c. Similarly, the second isolation trench 4 has a second side surface portion composed of the side surfaces 4a and 4b, and a second bottom surface portion composed of the bottom surface 4c. The third isolation trench 5 has a third side surface portion composed of the side surfaces 5a and 5b, and a third bottom surface portion composed of the bottom surface 5c. Each side surface portion is so formed as to extend from each corresponding bottom surface portion to the upper surface 1a of the semiconductor substrate 1. By forming respective trenches, the cell active area MA whose width W1 in the X direction is 30 nm, the peripheral first active area PA1 whose width W4 is 45 nm, and the peripheral second active area PA2 whose width W5 is 70 nm are formed, respectively.

Subsequently, as shown in FIG. 4, the non-flowable first isolation film 6 serving as the bottom-raised liner film is formed by the HDP-CVD method in such a way that the semiconductor substrate 1 is set in an inductive coupled plasma film-forming apparatus and then a silicon oxide film is formed under the following condition.

The film-forming apparatus is supplied with monosilane (SiH₄) of 25 sccm (flow rate), oxygen (O₂) of 65 sccm, and hydrogen (H₂) of 1000 sccm and with high-frequency source power of 15000 W and ion-accelerating high-frequency bias power of 3000 W under a constant pressure of 2 mTorr. The HDP-CVD method, which is different from the ordinary plasma CVD method, is a film-forming method by which deposition and sputter-etching are combined together. The HDP-CVD method realizes deposition with strong directionality by which a deposition rate at the side surfaces becomes extremely low. Therefore, if a specific condition is set under which a deposition rate (D) at the plane (bottom surface portion of the trench) becomes higher than a sputter-etching rate (S: sputter rate) as a low deposition rate at the side surfaces is maintained, the bottom-raised liner film 6 with large bottom-raising property can be formed.

For such condition adjustment, controlling the high-frequency power is effective. According to the above condition, the ratio of the high-frequency source power to the high-frequency bias power is 5, that is, the high-frequency source power and the high-frequency bias power are applied at a power ratio of 5. This makes a D/S ratio equal to or higher than 25. It is preferable that the D/S ratio be 20 or higher and 40 or lower. If the D/S ratio is lower than 20, forming the bottom-raised liner film 6 with a desired second thickness becomes difficult. If the D/S ratio is higher than 40, on the other hand, a deposition rate at the side surfaces increases, inviting blockage of the trench. According to this embodiment, in order to achieve the D/S ratio of 20 or higher, the power ratio should preferably be 4 or higher. Further reducing the bias power and increasing hydrogen supply are also effective in improving the bottom-raising property.

Under the above condition, the first dielectric film 6A made of the first isolation film 6 is formed in the first trench 3, the second dielectric film 6B made of the first isolation film 6 is formed in the second trench 4, and the third dielectric film 6C made of the first isolation film 6 is formed in the third trench 8c. In this stage, the first isolation film 6 is formed also on the surface of the mask film 2, as shown in FIG. 4.

The first dielectric film 6A has the first portion 6ab in contact with the first bottom surface portion 3c, and the second portion 6aa in contact with the first side surface portions 3a and 3b. The second portion 6aa is formed as a film with a uniform thickness that covers the entire first side surface portions 3a and 3b. The first portion 6ab has the first thickness T1 while second portion 6aa has the second thickness t1. The first thickness T1 is larger than the second thickness t1. By forming the first dielectric film 6A along the first bottom surface portion 3c and first side surface portions 3a and 3b in the first trench 3, the first gap 31a is formed.

The second dielectric film 6B has the third portion 6bb in contact with the second bottom surface portion 4c, and the fourth portion 6ba in contact with the second side surface portions 4a and 4b. The fourth portion 6ba is formed as a film with a uniform thickness that covers the entire first side surface portions 4a and 4b. The third portion 6bb has the third thickness T2 while fourth portion 6ba has the fourth thickness t2. The third thickness T2 is larger than the fourth thickness t2. By forming the second dielectric film 6B along the second bottom surface portion 4c and second side surface portions 4a and 4b in the second trench 4, the second gap 31b is formed.

The third dielectric film 6C has the fifth portion 6cb in contact with the third bottom surface portion 5c, and the sixth portion 6ca in contact with the third side surface portions 5a and 5b. The sixth portion 6ca is formed as a film with a uniform thickness that covers the entire first side surface portions 5a and 5b. The fifth portion 6cb has the fifth thickness T3 while sixth portion 6ca has the sixth thickness t3. The fifth thickness T3 is larger than the sixth thickness t3. By forming the second dielectric film 6C along the third bottom surface portion 5c and third side surface portions 5a and 5b in the third trench 5, the third gap 31c is formed.

According to this embodiment, each of the first, third, and fifth thicknesses T1, T2, and T3 is 70 nm, and each of the second, fourth, and sixth thicknesses t1, t2, and t3 is 4 nm. This means that in each trench with a different width, the dielectric film formed on the bottom surface portion is thicker than the dielectric film formed on the side surface portion and that in each trench with a different width, the ratio of the thickness of the dielectric film formed on the side surface portion to the thickness of the dielectric film formed on the bottom surface portion is identical.

According to the method of manufacturing the semiconductor device of this embodiment, the dielectric film is formed such that the ratio of the thickness of the dielectric film formed on the side surface portion to the thickness of the dielectric film formed on the bottom surface portion is 1/10 or lower. In this embodiment, this thickness ratio is about 1/17. Each of the dielectric films 6A, 6B, and 6C thus elevates the position of the bottom surface of each trench while keeping a positional shift of the trenches' side surfaces small. In this manner, the non-flowable first, second, and third dielectric films 6A, 6B, and 6C are so formed that they cover the side surfaces and bottom surfaces of the trenches 3, 4 and 5, respectively. The first, second, and third dielectric films 6A, 6B, and 6C that do not accompany stress creation or cancel out stresses applied by the second isolation film 7, which will be described later, protect the bottoms of respective trenches 3, 4, and 5. As a result, development of a dislocation defect can be avoided. To avoid development of a dislocation defect, it is preferable to determine each of the first, third, and fifth thicknesses T1, T2 and T3 to be ⅕ to ½ of the depth H2 of the third trench 5. If each of the first, third, and fifth thicknesses is smaller than ⅕ of the depth H2, avoiding dislocation development becomes difficult. If each of the first, third, and fifth thicknesses is larger than ½ of the depth H2, on the other hand, the opening of the first trench 3 with the smallest opening width is blocked easily, which facilitates formation of a void in the trench. When the depth H2 of the third trench 35 is determined to be, for example, 350 nm, as in the case of this embodiment, each of the first, third, and fifth thicknesses T1, T2 and T3 should preferably be determined to be 70 to 175 nm.

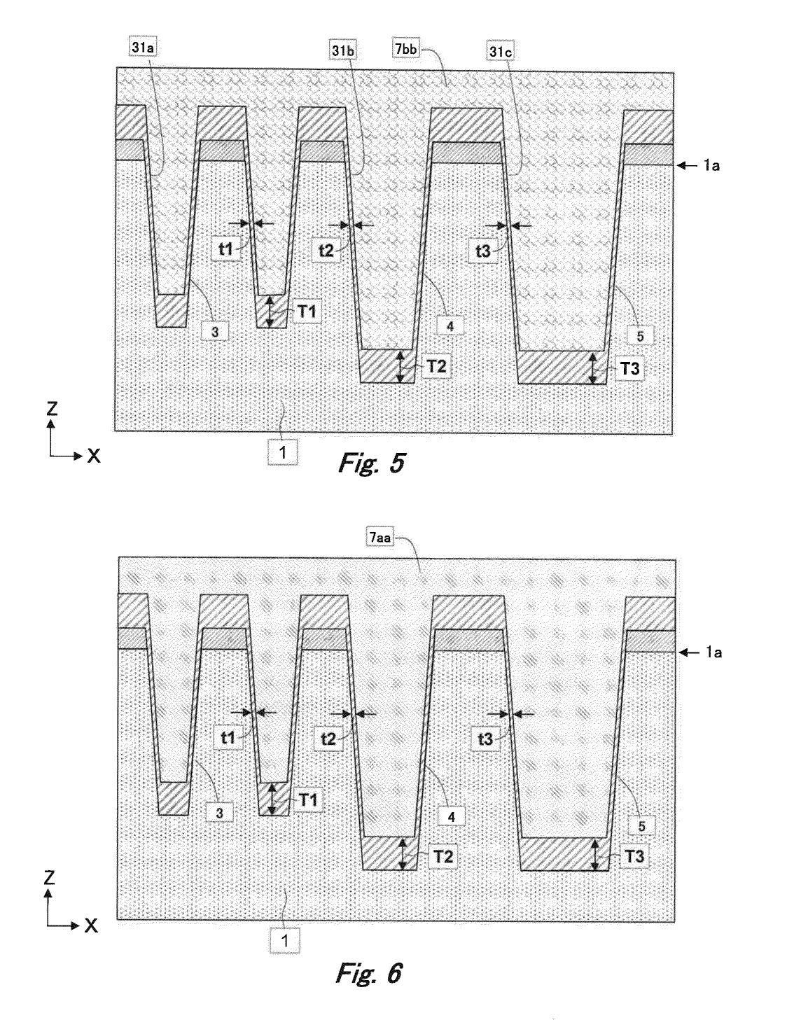

Subsequently, as shown in FIG. 5, a flowable film 7bb covering the surface of the first isolation film 6 and filling the first, second, and third gaps 31a, 31b, and 31c is formed. The flowable film 7bb is formed such that it completely fills each of the first, second, and third gaps 31a, 31b, and 31c and its surface becomes higher than the upper surface of the mask film 2. The flowable film 7bb can be formed by, for example, a method of forming a flowable silazane compound film by the CVD method or a SOD method of applying known polysilazane dissolved in a solvent, as an SOD film.

“Flowable silazane compound” mentioned above is a compound containing Si—NH bonds, which is a silazane-based compound in its liquid (gelled) state. The flowable silazane compound film is formed by the CVD method, by which a raw compound containing Si and N (e.g., aminosilane, silazane, etc.) is vaporized, is partly reformed when necessary, and is deposited as a silazane compound, which is fluidized to be able to fill respective trenches. The known SOD film formed by the SOD method is applied as a liquid film and is, therefore, obviously flowable enough to fill respective trenches.

FIG. 6 will then be referred to. The flowable film 7bb formed in such a manner as shown in FIG. 5 can be transformed into a second isolation film 7aa made of a silicon oxide film through a thermal treatment in both cases of film formation by CVD and film formation by the SOD method. This thermal treatment is performed at least under an oxidation atmosphere in order to transform Si—NH bonds into Si—O bonds. In addition to a single-step thermal treatment, a multi-step thermal treatment is performed as a more effective treatment. For example, a first step of the thermal treatment is performed to transform Si—NH bonds into Si—O bonds under a low-temperature oxidation atmosphere at 400 to 500° C., and a second step of the thermal treatment is performed to transform remaining Si—OH bonds into Si—O bonds and densify the bond structure under an oxidation atmosphere at 700 to 800° C. Through this multi-step thermal treatment, degassing the silicon oxide film (removing NO, H₂O, etc.) becomes easier at the first step of the thermal treatment carried out before sufficient densification of the flowable film 7bb. The oxidation atmosphere is created by oxidation using known oxidants, such as oxygen (O₂), ozone (O₃), and water (H₂O). Wet oxidation using water (water vapor) is particularly referable. It is preferable that the second step of the thermal treatment performed at 700 to 800° C. under the wet oxidation atmosphere be finished within 30 to 120 minutes.

As described above, the flowable film 7bb is transformed into the second isolation film 7aa through the oxidation-annealing treatment. If the second isolation film 7aa is formed without forming the first isolation film 6, a stress to the semiconductor substrate is created because of the shrinkage of the flowable film that occurs during the oxidation-annealing treatment. This stress leads to development of a dislocation defect. According to this embodiment, however, the non-flawable first isolation film 6 is so formed as to cover the bottom surfaces including bottom corners of the trenches 3, 4, and 5. In other words, the first isolation film 6 that does not accompany stress creation or cancels out stresses applied by the second isolation film 7aa protects the bottoms of respective trenches 3, 4, and 5. As a result, development of a dislocation defect can be avoided. Because only the thin first isolation film 6 is formed on the side surface portion of each trench, void formation is prevented even at the narrowest first trench 3, which, therefore, can easily be filled with the flowable film 7bb.

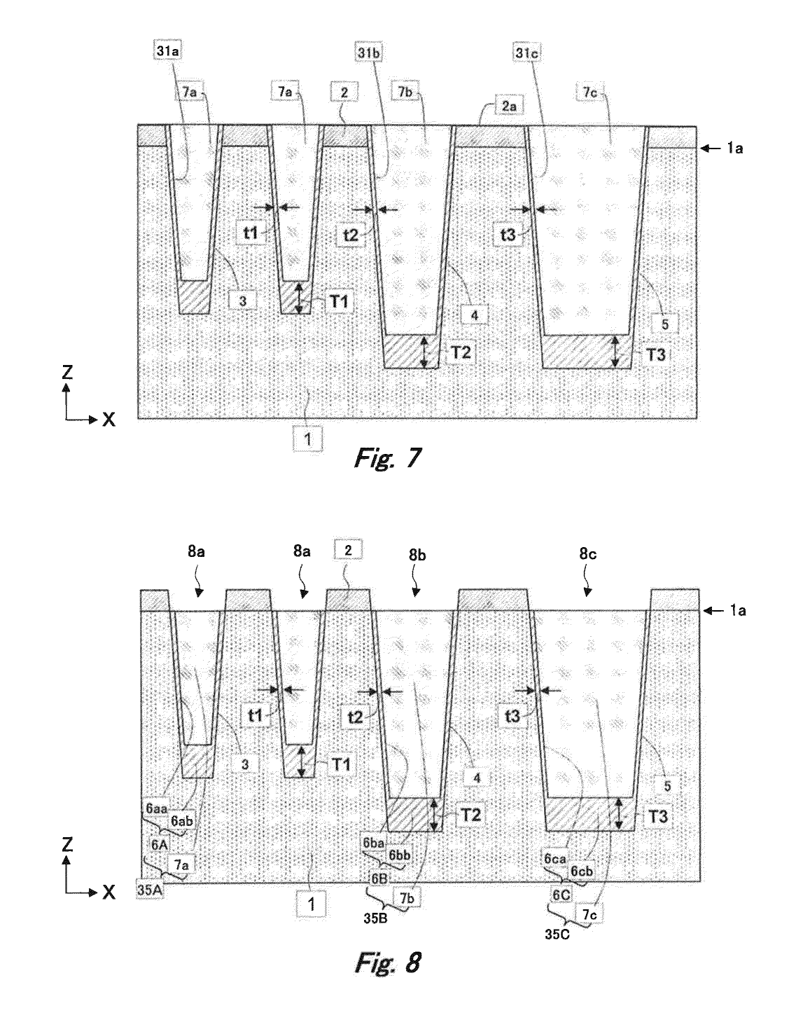

Subsequently, as shown in FIG. 7, the first isolation film 6 and second isolation film 7aa formed on the mask film 2 are removed by CMP method, which is continued until the upper surface of the silicon nitride film making up the mask film 2 is exposed. As a result, the second isolation film 7aa is divided into the second isolation film 7a filling the first gap 31a, the second isolation film 7b filling the second gap 31b, and the second isolation film 7c filling the third gap 31c.

Subsequently, the second isolation film 7aa is subjected to a thermal treatment at 950 to 1050° C. under an inert atmosphere. Through this thermal treatment, the second isolation film 7aa is densified into a silicon oxide film having wet etching resistance equivalent to that of an HDP-silicon oxide film making up the first isolation film 6.

Subsequently, as shown in FIG. 8, the first isolation film 6 (6aa, 6ba, 6ca) and second isolation film 7aa (7a, 7b, 7c) are etched back until their heights are reduced to the height of the upper surface 1a of the semiconductor substrate 1. This etching back is performed as wet etching using a solution containing a hydrofluoric acid (HF). As a result of this etching back process, the mask film 2 is left projected from the upper surface 1a of the semiconductor substrate. The first trench 3 is filled with the first isolation dielectric film 35A composed of a lamination of the first dielectric film 6A (first isolation film 6) and the second isolation film 7a, the second trench 4 is filled with the second isolation dielectric film 35B composed of a lamination of the second dielectric film 6B (first isolation film 6) and the second isolation film 7b, and the third trench 5 is filled with the third isolation dielectric film 35C composed of a lamination of the third dielectric film 6C (first isolation film 6) and the second isolation film 7c.

Subsequently, as shown in FIG. 1B, the mask film 2 made of the silicon nitride film is removed selectively by wet etching method using a hot phosphoric acid. The etching with the hot phosphoric acid realizes an etching rate at the silicon oxide film far lower than an etching rate at the silicon nitride film. As a result, the isolation dielectric films 35A, 35B, and 35C whose surfaces are co-planar with the upper surface of the semiconductor substrate are formed.

Following this etching process, as shown in FIGS. 2A, 2B, and 2C, the conventional processes including formation of the dielectric film covering the peripheral circuit area PC and formation of cell gate electrodes in the memory cell area MC are carried out to complete the semiconductor device serving as a DRAM.

FIG. 9 is a process diagram showing a method of manufacturing the semiconductor device according to a preferred second embodiment of the present invention.

According to the first embodiment, the trenches are formed such that the depth H1 of the first trench 3 having the smallest opening width is different from the depth H2 of the second trench 4 and third trench 5 each having the opening width larger than that of the first trench 3, as shown in FIG. 1B. The method of manufacturing the semiconductor device according to the second embodiment is provided as a method by which trenches with different opening widths are so formed as to have the identical depth.

In the first embodiment, the condition for the anisotropic dry etching performed during the trench forming process specifies use of the mixed gas plasma made up of hydrogen bromide (HBO of 70 sccm, chloride (Cl₂) of 70 sccm, sulfur hexafluoride (SF₆) of 10 sccm, and oxygen (O₂) of 20 sccm under a pressure of 20 mToor and application of the high-frequency source power of 1500 W and the ion-accelerating bias power of 200 W. Under this etching condition, a loading effect is produced, which brings a tendency that etching in a region with a small etching area becomes slower while etching in a region with a large etching area becomes faster. As a result, a trench with a large opening width is etched deeper.

According to this embodiment, under the above condition, the bias power is reduced to 100 W or less, preferably to about 50 W. Under the above condition, an SF₆ flow rate expressed as SF₆/(HBr+Cl₂+SF₆+O₂) is 0.059. This SF₆ flow rate is reduced to about 0.03. An O₂ flow rate expressed as O₂/(HBr+Cl₂+SF₆+O₂) is 0.118. This O₂ flow rate is reduced to about 0.06. By using this newly set condition, the depth of each trench can be made identical, as shown in FIG. 9.

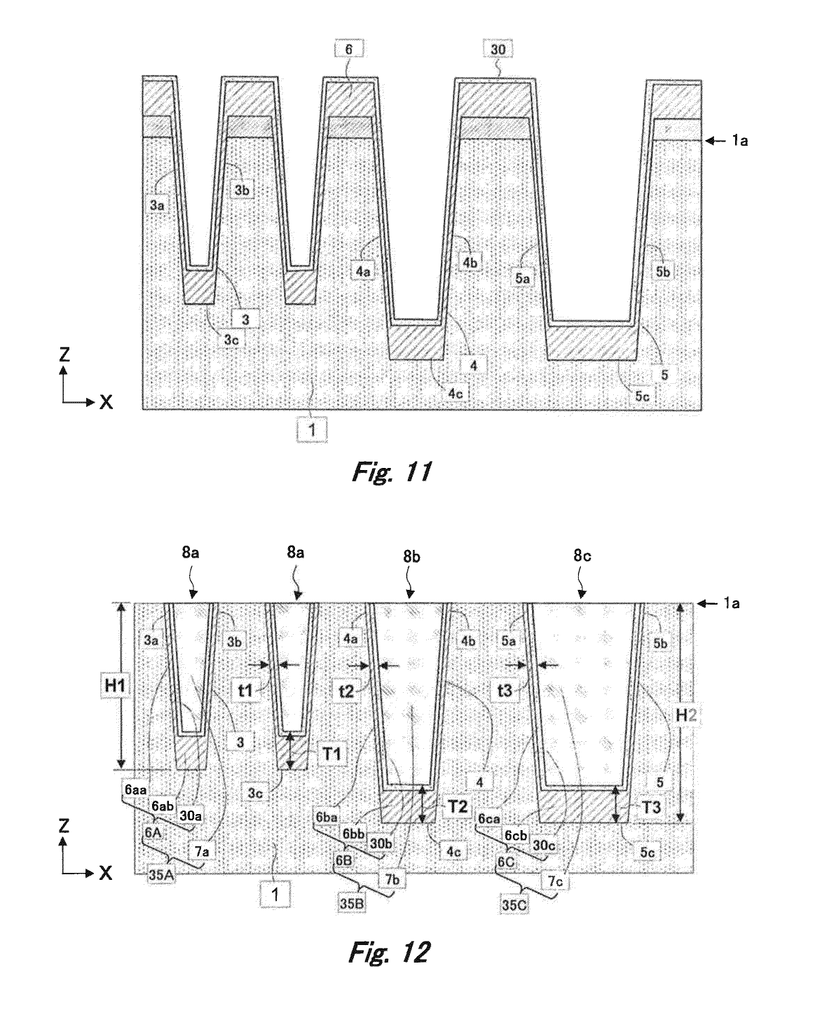

FIGS. 11 and 12 are process diagrams showing a method of manufacturing the semiconductor device according to a preferred third embodiment of the present invention. The semiconductor device of the third embodiment is different from the semiconductor device of the first embodiment in that the first dielectric film 6A is made of a lamination of the first isolation film 6 and a third isolation film 30. It is understood by observing the first isolation dielectric film 35A that the first isolation dielectric film 35A is made up of three layers of films, i.e., the first isolation films 6aa and 6ab, a third isolation film 30a, and the second isolation film 7a. To put it another way, the third isolation film 30a with a uniform thickness is disposed between the second isolation film 7a and the first isolation films 6aa and 6ab. The third isolation film 30a is not flowable and is formed into a conformal shape, so that its thickness is uniform on every part thereof. The second isolation dielectric film 35B and third isolation dielectric film 35C are identical in structure with the first isolation dielectric film 35A. The first dielectric film 6A, therefore, is composed of first portions 6ab and 30a disposed to be in contact with the first bottom surface portion 3c and second portions 6aa and 30a disposed to be in contact with the first side surface portions 3a and 3c. The thickness T1 of the first portions is larger than the thickness t1 of the second portions in the same manner as in the first embodiment.

The third isolation film 30a is made of a silicon oxy-nitride film (SiON film) of 2 to 5 nm in thickness. When the flowable film is formed directly on the silicon oxide film, the presence of a part with inferior film bonding in the trench leads to insufficient film deposition. This may eventually leave a bubble hole in the second isolation film 7. The SiON film improves film bonding, thus preventing such a problem. It is preferable that the nitrogen content of the SiON film be 10 to 20 atom % and that the ratio of the number of oxygen atoms to the number of nitrogen atoms be 2.2 to 5.5.

After the first isolation film 6 is formed through the same process as described in the first embodiment, as shown in FIG. 4, the third isolation film 30 made of a silicon oxy-nitride film is formed. The silicon oxy-nitride film can be formed by, for example, CVD method using dichlorosilane (SiH₂Cl₂), ammonium (NH₃), and nitrous oxide (N₂O) as feed gases. The nitrogen content of the SiON film is determined to be 10 to 20 atom % and the ratio of the number of oxygen atoms to the number of nitrogen atoms is determined to be 2.2 to 5.5 by adjusting supply of NH₃ and N₂O.

Following the formation of the silicon oxy-nitride film of 3 nm in thickness, the flowable film 7bb is formed, as shown in FIG. 5, after which the semiconductor device can be manufactured according to the process described in the first embodiment. According to the third embodiment, the first isolation film 6 made of the silicon oxide film is formed by the HDP-CVD method, and then the SiON film is formed on the first isolation film 6, after which the flowable film is formed. This process flow is effective in avoiding formation of a bubble hole in the flowable film.

The preferred embodiments of the present invention have been described above. The present invention is not limited to the above embodiments but may be modified into various forms of applications on the condition that the modification does not deviate from the substance of the invention. It is obvious that modified forms of applications are also included in the scope of the invention.

What is claimed is:

1. A semiconductor device, comprising:
a substrate including an upper surface,
a first trench selectively formed in the substrate so that the substrate includes a first bottom surface portion and a first side surface portion extending from the first bottom surface portion to the upper surface, the first trench being defined by the first bottom surface portion and the first side surface portion;
a second trench selectively formed in the substrate so that the substrate includes a second bottom surface portion and a second side surface portion extending from the second bottom surface portion to the upper surface, the second trench being defined by the second bottom surface portion and the second side surface portion, the second trench being formed larger in width than the first trench;
a first dielectric film formed in the first trench along the first bottom surface portion and the first side surface portion with leaving a first gap in the first trench, the first bottom surface portion being covered approximately conformably with a first part of the first dielectric film and the first side surface portion being covered approximately conformably with a second part of the first dielectric film, the first part being larger in thickness than the second part; and
a second dielectric film formed in the second trench along the second bottom surface portion and the second side surface portion with leaving a second gap in the second trench, the second bottom surface portion being covered approximately conformably with a third part of the second dielectric film and the second side surface portion being covered approximately conformably with a fourth part of the second dielectric film, the third part being larger in thickness than the fourth part.

2. The semiconductor device according to claim 1, wherein the substrate further comprises:
a third trench including a third bottom surface portion and a third side surface portion extending from the third bottom surface portion to the upper surface, the third trench being defined by the third bottom surface portion and the third side surface portion; and
a third dielectric film formed in the third trench along the third bottom surface portion and the third side surface portion with leaving a third gap in the third trench, the third bottom surface portion being covered approximately conformably with a fifth part of the third dielectric film and the third side surface portion being covered approximately conformably with a sixth part of the third dielectric film, the fifth part being larger in thickness than the sixth part.

3. The semiconductor device according to claim 2, wherein the first part of the first dielectric film, the third part of the second dielectric film and the fifth part of the third dielectric film are equal in thickness to each other.

4. The semiconductor device according to claim 3, wherein the second part of the first dielectric film, the fourth part of the second dielectric film and the sixth part of the third dielectric film are equal in thickness to each other.

5. The semiconductor device according to claim 3, wherein a ratio of a thickness of the second part of the first dielectric film to a thickness of the first part of the first dielectric film is equal to or smaller than 0.1.

6. The semiconductor device according to claim 3, wherein the third trench has a third depth and the fifth part of the third dielectric film has a thickness defined between 0.2 to 0.5 times as large as the third depth.

7. The semiconductor device according to claim 6, wherein the first trench has a first depth, the second trench has a second depth and the first depth is smaller than each of the second depth and third depth.

8. The semiconductor device according to claim 6, wherein the first trench has a first depth, the second trench has a second depth and the first depth, the second depth and the third depth are equal to each other.

9. The semiconductor device according to claim 2, further comprising a second isolation films each filling a corresponding one of the first gap, the second gap and the third gap.

10. The semiconductor device according to claim 9, wherein each of the first dielectric film, the second dielectric film, third dielectric film and the second isolation films includes a silicon dioxide film.

11. The semiconductor device according to claim 9, wherein the semiconductor device further comprises third isolation films disposed between the first dielectric film and the second isolation film corresponding to the first dielectric film, between the second dielectric film and the second isolation film corresponding to the second dielectric film and between the third dielectric film and the second isolation film corresponding to the third dielectric film, respectively.

12. The semiconductor device according to claim 11, wherein each of the third isolation films includes a silicon nitride film.

13. A semiconductor device, comprising:
a substrate including an upper surface;
a first trench selectively formed in the substrate so that the substrate includes a first bottom surface portion and a first side surface portion extending from the first bottom surface portion to the upper surface, the first trench being defined by the first bottom surface portion and the first side surface portion;
a second trench selectively formed in the substrate so that the substrate includes a second bottom surface portion and a second side surface portion extending from the second bottom surface portion to the upper surface, the second trench being defined by the second bottom surface portion and the second side surface portion, the second trench being formed deeper in depth than the first trench;
a first dielectric film formed in the first trench along the first bottom surface portion and the first side surface portion with leaving a first gap in the first trench, the first bottom surface portion being covered approximately conformably with a first part of the first dielectric film and the first side surface portion being covered approximately conformably with a second part of the first dielectric film, the first part being larger in thickness than the second part; and
a second dielectric film formed in the second trench along the second bottom surface portion and the second side surface portion with leaving a second gap in the second trench, the second bottom surface portion being covered approximately conformably with a third part of the second dielectric film and the second side surface portion being covered approximately conformably with a fourth part of the second dielectric film, the third part being larger in thickness than the fourth part.

14. A method of forming a semiconductor device, comprising:
forming a mask film having a first hole pattern and a second hole pattern on an upper surface of a substrate;
forming a first trench at the first hole pattern and a second trench at the second hole pattern in the substrate such that the first trench has a first bottom surface portion and a first side surface portion extending from the first bottom surface portion to the upper surface of the substrate, the second trench has a second bottom surface portion, which is larger in width than the first bottom surface portion, and a second side surface portion extending from the second bottom surface portion to the upper surface of the substrate;
forming a first isolation film to cover an upper surface of the mask film, the first bottom surface portion and the first side surface portion, the second bottom surface portion and the second side surface portion with remaining a first gap in the first trench and a second gap in the second trench, a first part of the first isolation film covering the first bottom surface portion being controlled to be thicker than a second part of the first isolation film covering the first side surface portion, a third part of the first isolation film covering the second bottom surface portion being controlled to be thicker than a fourth part of the first isolation film covering the second side surface portion;
forming a second isolation film on the first isolation film to fill the first gap and the second gap;
removing a part of the second isolation film to expose an upper surface of the mask film.

15. The method of forming a semiconductor device according to claim 14, wherein the first isolation film is formed by HDP-CVD method and the second isolation film is formed by flowable-CVD method or SOD method.

16. The method of forming a semiconductor device according to claim 15, wherein the HDP-CVD method is performed on condition that a ratio of a growth rate to a sputter rate becomes 20 to 40.

17. The method of forming a semiconductor device according to claim 14, further comprising, performing a wet etching the mask film and another part of the second isolation film formed in a higher level of the upper surface of the substrate after removing the part of the second isolation film

18. The method of forming a semiconductor device according to claim 14, wherein forming the first trench at the first hole pattern and a second trench at the second hole pattern in the substrate includes forming a third trench at a third hole pattern of the mask film such that the third trench has a third bottom surface portion which is larger in width than the second bottom surface and a third side surface portion extending from the third bottom surface portion to the upper surface of the substrate.

19. The method of forming a semiconductor device according to claim 18, wherein the third bottom surface portion is covered with a fifth part of the first isolation film and the third side surface portion is covered with a sixth part of the first isolation film, the fifth part and the sixth part being defining a third gap therebetween, the third gap being filled with the second isolation film.

20. The method of forming a semiconductor device according to claim 18, further comprising, forming a third isolation film including a silicon nitride film between the first isolation film and the second isolation film after forming the first isolation film and before forming the second isolation film.
